(19) United States
(12) Patent Application Publication
(10) Pub. No.: US 2008/0134004 A1
(43) Pub. Date: Jun. 5, 2008

(54) RECORDING AND/OR REPRODUCING APPARATUS AND METHOD

(75) Inventors: Hyun-jeong PARK, Suwon-si (KR); Joo-seon KIM, Seongnam-si (KR); Ki-seon CHO, Seoul (KR); Yong-suk AHN, Gunpo-si (KR); Jin-seok HONG, Suwon-si (KR)

Correspondence Address: STEIN, MCEWEN & BUI, LLP, 1400 EYE STREET, NW, SUITE 300, WASHINGTON, DC, 20005, US

(73) Assignee: Samsung Electronics Co., Ltd., Suwon-si (KR)

(21) Appl. No.: 11/946,246

(22) Filed: Nov. 28, 2007

(30) Foreign Application Priority Data
Dec. 5, 2006 (KR) 2006-122580
Mar. 27, 2007 (KR) 2007-30052

(51) Int. Cl. G11C 29/00

(52) U.S. Cl. 714/763

(57) ABSTRACT

A recording method includes storing at least one Error Correction Code (ECC) data cluster in a primary memory, scrambling data frames contained in the stored ECC data cluster using scramble shift values, storing data in a secondary memory, the data comprising data which is not contained in the data frames and is contained in the ECC cluster and a data block generated by the scrambling of the data frames, interleaving the data stored in the secondary memory, and recording the interleaved data on a disc.

### CROSS-REFERENCE TO RELATED APPLICATIONS

This application claims the benefit of Korean Application No. 2006-122580, filed Dec. 5, 2006 and Korean Patent Application No. 2007-30052, filed Mar. 27, 2007 in the Korean Intellectual Property Office, the disclosures of which are incorporated herein by reference.

### BACKGROUND OF THE INVENTION

1. Field of the Invention

Aspects of the present invention relate to a disc recording and/or reproducing method and apparatus, and more particularly, to a high-speed disc recording and/or reproducing method and apparatus.

2. Description of the Related Art

Examples of optical discs include Digital Versatile Discs (DVDs), High Density (HD)-DVDs, and Blu-ray Discs (BDs). BDs are a widely used type of digital storage media which provide high resolution images, since a single layer BD stores approximately 25 GB of data and a dual layer BD stores approximately 50 GB. Generally, a recording speed at which data is recorded onto a BD is approximately 9 MB/sec. Thus, a user recording data onto a BD generally requires approximately 50 minutes to record 25 GB of data onto the BD, and approximately 100 minutes to record 50 GB of data onto the BD. Accordingly, the recording of data onto a high-density disc, such as a BD, at high speed is being developed.

However, in high-speed recording, an operational frequency of an optical disc drive is higher compared to relatively low-speed recording. Thus, power consumption of the optical disc drive increases since the optical disc drive rotates the optical disc at a higher frequency. Accordingly, chip designs are being developed to improve high speed recording.

In the case of BDs, interleaved data is recorded. Thus, in high-speed recording, the size of an interleaving memory employed in the optical disc drives should be larger than a memory used in low-speed recording. The reason for this is because even if a memory having a high processing speed is used to reduce a processing time for interleaving, the more data which is stored in a memory, the better the interleaving is performed. However, an increase in memory size results in an increase in the area of chips employed in optical disc drives, resulting in a reduction in price competitiveness of the optical disc drives.

Meanwhile, in high-speed reproduction, like high-speed recording, an operational frequency of optical disc drives is also higher compared to low-speed reproduction. Thus, power consumption of the optical disc drives increases. Accordingly, chip designs are being developed to improve high-speed reproducing.

In addition, if error correction cannot be performed during data reproduction within the time required to decode one data block which is encoded using an Error Correction Code (ECC), the error correction is considered a failure. However, the higher a reproduction speed is, the more errors occur in a channel, resulting in a high possibility that error correction will not be performed within the time taken to decode one ECC block. Thus, the higher a reproduction speed is, the more an error correction load increases.

### SUMMARY OF THE INVENTION

Aspects of the present invention provide a high-speed recording method and apparatus to record data on a disc at high speed while decreasing an operational frequency and minimizing the size of an interleaving memory.

Aspects of the present invention also provide a high-speed reproducing method and apparatus to reduce power consumption and to make chip design easier by decreasing an operational frequency.

Aspects of the present invention further provide a high-speed reproducing method and apparatus to reduce an error correction load due to high-speed reproduction.

According to an aspect of the present invention, a high-speed recording method includes storing at least one Error Correction Code (ECC) data cluster in a primary memory; scrambling data frames contained in the stored ECC data cluster using scramble shift values; storing data in a secondary memory, the data comprising data which is not contained in the data frames and is contained in the ECC data cluster, and a data block generated by the scrambling of the data frames, interleaving the data stored in the secondary memory, and recording the interleaved data on a disc.

According to an aspect, the high-speed recording method further includes equally dividing the ECC data cluster stored in the primary memory into N pieces of data in perpendicular directions to each other, and reading the N pieces of data, wherein the storing of the data in the secondary memory includes storing the data by alternately using a plurality of memories which has a size according to the N pieces of data.

According to another aspect of the present invention, a high-speed recording apparatus includes a primary memory to store at least one Error Correction Code (ECC) data cluster, a scramble shift value transmitting unit to transmit scramble shift values based on physical sector numbers (PSNs), a first scrambler to scramble data frames of the ECC data cluster read from the primary memory using the scramble shift values, a secondary memory to store data, the data comprising data which is not contained in the data frames and is contained in the ECC data cluster read from the primary memory and a data block output from the first scrambler, a recording processing unit to interleave the data read from the secondary memory and to record the interleaved data on a high-density disc, and a controller to control read and/or write operations of the primary memory and the secondary memory, controlling transmission of the data read from the primary memory, and providing the physical sector numbers to the scramble shift value providing unit, wherein the ECC cluster stored in the primary memory contains the data frames and data that is not contained in the data frames.

According to another aspect of the present invention, the controller equally divides the data contained in the ECC cluster stored in the primary memory into N pieces of data in perpendicular directions to each other and reads the N pieces of data, the secondary memory includes a plurality of memories having a size according to the N pieces of data, and the controller controls read and/or write operations of the plurality of memories so that the data read from the primary memory is alternately stored in the plurality of memories.

According to another aspect of the present invention, a high-speed reproducing method includes demodulating data read from a disc, deinterleaving the demodulated data, generating syndromes using the deinterleaved data; descrambling data contained in a data block among the deinterleaved data using descramble shift values; calculating error detection codes (EDCs) using non-descrambled data among the deinterleaved data, the descrambled data, and an EDC table, storing the descrambled data, the non-descrambled data, and the syndromes, and correcting errors of the stored descrambled data and the stored non-descrambled data using the stored syndromes.

According to another aspect of the present invention, a high-speed reproducing apparatus includes a demodulator to demodulate data read from a disc, a deinterleaver to deinterleave the data demodulated by the demodulator, a syndrome generator to generate syndromes using the data input from the deinterleaver, a descrambler to descramble data contained in a data block among the deinterleaved data using descramble shift values, an error detection code (EDC) calculator to calculate EDCs using non-descrambled data among the deinterleaved data, the data descrambled by the descrambler, and an EDC table, a memory to store the descrambled data, the non-descrambled data, and the syndromes, and an error correction unit to correct errors of the descrambled data and the non-descrambled data stored in the memory by reading the syndromes from the memory.

Additional aspects and/or advantages of the invention will be set forth in part in the description which follows and, in part, will be obvious from the description, or may be learned by practice of the invention.

### BRIEF DESCRIPTION OF THE DRAWINGS

These and/or other aspects and advantages of the invention will become more apparent and more readily appreciated from the following description of the embodiments, taken in conjunction with the accompanying drawings of which:

FIG. 1 is a block diagram of a high-speed recording apparatus according to an embodiment of the present invention;

FIG. 2 illustrates a memory map of a primary memory illustrated in FIG. 1;

FIG. 3 illustrates the primary memory illustrated in FIG. 1, when the primary memory is divided by 4;

FIG. 4 is a diagram illustrating how to operate a secondary memory when the primary memory illustrated in FIG. 1 is divided by 4;

FIG. 5 illustrates a structure of Burst Indicating Sub-code (BIS) cluster memories included in the secondary memory illustrated in FIG. 1;

FIG. 6 is a block diagram of a high-speed recording apparatus according to another embodiment of the present invention;

FIG. 7 is a block diagram of a high-speed recording apparatus according to still another embodiment of the present invention;

FIG. 8 is a flowchart of a high-speed recording method according to an embodiment of the present invention;

FIG. 9 is a flowchart of an Error Correction Code (ECC) cluster storing process illustrated in FIG. 8;

FIG. 10 is a flowchart of a high-speed recording method according to another embodiment of the present invention;

FIG. 11 is a block diagram of a high-speed reproducing apparatus according to an embodiment of the present invention;

FIG. 12 illustrates a map of memories included in a deinterleaver when a disc illustrated in FIG. 11 is a Digital Versatile Disc (DVD) or High Density (HD)-DVD;

FIG. 13 illustrates a memory map when the disc illustrated in FIG. 11 is a DVD or HD-DVD;

FIG. 14 illustrates a memory map when the disc illustrated in FIG. 11 is a Blu-ray Disc (BD);

FIG. 15 is a flowchart of a high-speed reproducing method according to an embodiment of the present invention; and

FIG. 16 is a flowchart of an error correcting process using syndromes in the high-speed reproducing method illustrated in FIG. 15.

### DETAILED DESCRIPTION OF THE EMBODIMENTS

Reference will now be made in detail to the present embodiments of the present invention, examples of which are illustrated in the accompanying drawings, wherein like reference numerals refer to the like elements throughout. The embodiments are described below in order to explain the present invention by referring to the figures.

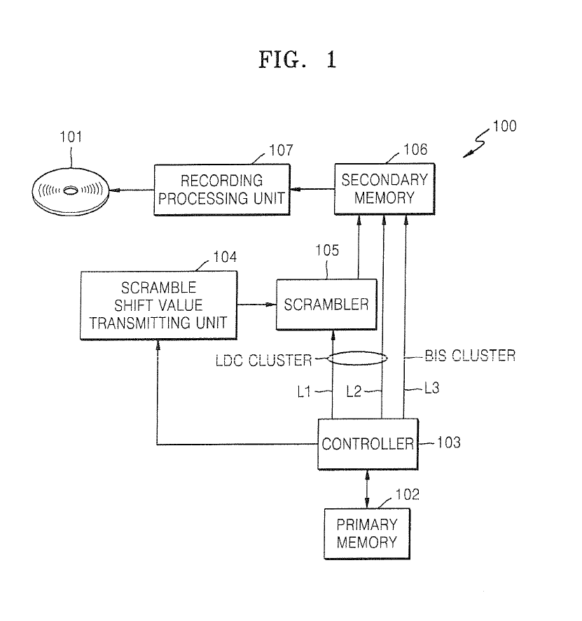

FIG. 1 is a block diagram of a high-speed recording apparatus 100 according to an embodiment of the present invention. Referring to FIG. 1, the high-speed recording apparatus 100 is used with a disc 101 and includes a primary memory 102, a controller 103, a scramble shift value transmitting unit 104, a scrambler 105, a secondary memory 106, and a recording processing unit 107.

According to an aspect of the present invention, the disc 101 is a high-density disc, such as a Blu-ray Disc (BD), or an optical disc with a lower recording density, such as a Digital Versatile Disc (DVD), a High Density (HD)-DVD, a compact disc (CD), etc. Hereinafter, it is assumed that the disc 101 is a high-density disc, such as a BD.

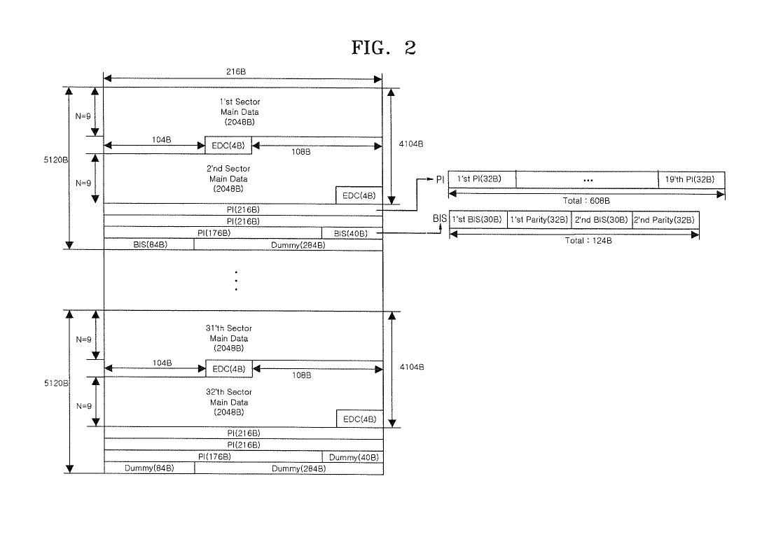

The primary memory 102 stores at least one Error Correction Code (ECC) cluster of data, also known as an ECC data cluster, that is to be recorded. When the disc 101 is a BD, an ECC cluster may be configured as illustrated in FIG. 2, although is not limited thereto. FIG. 2 is a memory map of the primary memory 102 and shows a data structure of the ECC cluster stored in the primary memory 102.

Referring to FIG. 2, the ECC cluster has 32 sectors. The size of a main data unit in each sector is 2048 bytes. The main data is made up of user data transmitted from a host (not shown), such as a computer. Thus, since the main data unit in one sector corresponds to user data of one data frame, an ECC cluster includes 32 data frames.

The ECC cluster of the memory map illustrated in FIG. 2 further includes a 4-byte Error Detection Code (EDC) in each sector, a 608-byte Parity Input (PI) in every other sector, and a 124-byte Burst Indicating Sub-code (BIS) in every other sector. The BIS is assigned up to a 24^{th} sector. Thus, no BIS exists in 31^{st} and 32^{nd} sectors.

According to an aspect of the present invention, the ECC cluster illustrated in FIG. 2 includes a Long Distance Code (LDC) cluster and a BIS cluster. The LDC cluster includes data frames and LDC parities. Although each data frame is made up of main data and the EDC illustrated in FIG. 2, if the data frame is scrambled according to an embodiment of the present invention, the data frame is defined as a data block. Each EDC is stored immediately next to the main data unit of one sector. Thus, each EDC is stored immediately next to user data of one data frame. The main data and the EDCs are unscrambled data. Each LDC parity is made up of a PI illustrated in FIG. 2. Each LDC parity, which is stored in every other sector, has 19 sequentially stored 32-byte parities.

The BIS cluster includes BIS blocks and BIS parities. Two BIS blocks and two BIS parities are alternately stored in every other sector of the memory map, as illustrated in FIG. 2. Thus, data, which is not contained in the data frames included in the ECC cluster illustrated in FIG. 2, includes the LDC parities and the BIS cluster.

According to an aspect of the present invention, the primary memory 102 is a Synchronous Dynamic Random Access Memory (SDRAM). In addition, the primary memory 102 maybe disposed outside of a chip installed in an optical disc drive (not shown) included in the high-speed recording apparatus 100 illustrated in FIG. 1. Thus, the primary memory 102 may be defined as an external memory. However, it is understood that the primary memory 102 is not limited to being an SDRAM, and may instead be various other types of memories, such as a DRAM, an eDRAM, an SRAM, or other types of non-volatile memories known in the art. Additionally, the primary memory 102 is not limited to being disposed outside of the chip installed in the optical disc drive, and may instead be integrally formed with the chip.

The controller 103 controls read and/or write operations of the primary memory 102 and the secondary memory 106 and transmission of data read from the primary memory 102. Thus, the controller 103 may be defined as a memory controller or a memory management unit.

The controller 103 transmits physical sector numbers (PSNs) to the scramble shift value transmitting unit 104. The scramble shift value transmitting unit uses the transmitted PSNs to generate scramble shift values. That is, before reading data stored in the primary memory 102 on an ECC-cluster-by-ECC-cluster basis, the controller 103 reads PSNs contained in each BIS cluster stored in the primary memory 102 and transmits the read PSNs to the scramble shift value transmitting unit 104. Each PSN is contained in a BIS block.

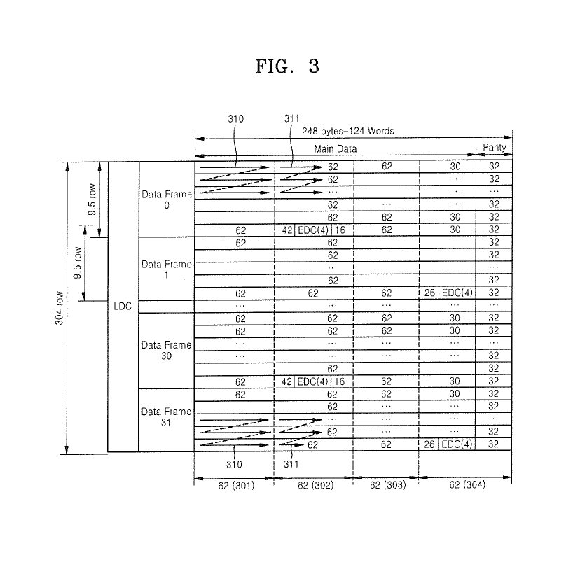

The controller 103 reads the ECC cluster stored in the primary memory 102. The controller 103 can sequentially read the ECC cluster stored in the primary memory 102. Alternatively, the controller 103 can equally divide the ECC cluster stored in the primary memory 102 into N pieces of data in a perpendicular direction and read the N pieces of data. For example, as illustrated in FIG. 3, the controller 103 first divides the ECC cluster stored in the primary memory 102 into 4 equal pieces of data in the perpendicular direction. Then, the controller 103 sequentially reads data of 62 bytes×304 rows stored in a region 301 in the direction of an arrow 310. Then, the controller 103 sequentially reads data of 62 bytes×304 rows stored in a region 302 in the direction of an arrow 311. Next, the controller 103 reads data of 62 bytes×304 rows stored in a region 303, and reads data of 62 bytes×304 rows stored in a region 304, as well as the data of 62 bytes×304 rows stored in the region 301. It can be determined by the number of bytes of a data width transmittable in the primary memory 102 how many pieces the ECC cluster stored in the primary memory 102 is equally divided into. The quadrisection described above corresponds to a case where the data width transmittable in the primary memory 102 is 62 bytes. Thus, the controller 103 can equally divide the ECC cluster stored in the primary memory 102 into 8 pieces of data in a perpendicular direction and read the 8 pieces of data. When the ECC cluster is equally divided into 8 pieces of data, the read region is divided according to units of 31 bytes×304 rows. It is understood that the ECC cluster may be divided into more or less than 8 pieces of data.

The controller 103 transmits data contained in the LDC cluster among the data read from the primary memory 102 via a line L1 and a line L2 and transmits data contained in the BIS cluster via a line L3. In particular, the controller 103 transmits the data frames contained in the LDC cluster via the line L1 and the LDC parities via the line L2. The controller 103 transmits the BIS blocks and the BIS parities contained in the BIS cluster via the line L3.

Thus, as illustrated in FIG. 3, when the ECC cluster stored in the primary memory 102 is equally divided into N pieces of data and read, the controller 103 transmits data contained in the data frames of the LDC cluster among the data stored in the regions 301, 302, 303, and 304 via the line L1, data contained in the LDC parities via the line L2, and data contained in the BIS cluster via the line L3.

The scramble shift value transmitting unit 104 generates a scramble shift value for each data frame based on the PSNs input from the controller 103. In detail, the scramble shift value transmitting unit 104 generates a scramble shift value by receiving a portion (e.g., PS 5 to PS 19) of the PSNs into a Linear Feedback Shift Register (LFSR) and shifting the portion of the PSNs. The scramble shift value transmitting unit 104 stores generated scramble shift values and transmits the stored scramble shift values to the scrambler 105. According to an aspect of the present invention, the scramble shift value transmitting unit 104 updates scramble shift values on an ECC-cluster-by-ECC-cluster basis. However, it is understood that the scramble shift value transmitting unit 104 is not limited to updating the scramble shift values on an ECC-cluster-by-ECC-cluster basis, and may instead update the scramble shift values on another basis, such as, for example, by a fraction of an ECC cluster or by multiple ECC clusters.

The scrambler 105 scrambles data frames received from the controller 103 using scramble shift values transmitted by the scramble shift value transmitting unit 104. The scrambler 105 scrambles each data frame received from the controller 103 by performing an operation, such as, for example, an exclusive OR operation on the data frame and a scramble shift value corresponding to the data frame, based on physical locations of the scramble shift value on the data frame and physical locations of data contained in the data frame. That is, each data frame including an EDC is 2052 bytes, and each scramble shift value of 2052 bytes is also generated. Thus, 0 to 2051 physical locations exist, and data, for example, having a physical location of 5 in the data frame is scrambled using a scramble shift value having a physical location of 5. It is understood that the scrambler 105 is not limited to performing an exclusive OR operation on the data frame and a scramble shift value corresponding to the data frame, and may perform various other types of logical operations instead of an exclusive OR operation to achieve similar results.

As described above, when the ECC cluster stored in the primary memory 102 is equally divided into N pieces of data and read, physical locations of data read by the controller 103 from each data frame follow the arrows 310 illustrated in FIG. 3. Thus, the scrambler 105 scrambles the data using a scramble shift value having the same physical location as the physical location of the data.

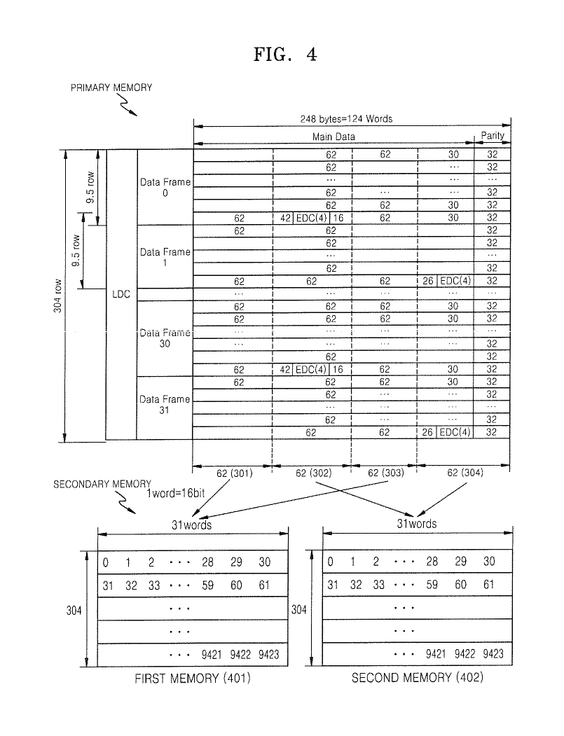

According to an aspect of the present invention, the secondary memory 106 stores a single ECC cluster. However, if the controller 103 equally divides the ECC cluster stored in the primary memory 102 into N pieces of data in the perpendicular direction and reads the N pieces of data as illustrated in FIG. 3, the secondary memory 106 includes a plurality of memories according to the N pieces of data, and the controller 103 alternatively stores the N pieces of data in the plurality of memories. That is, as illustrated in FIG. 4, the pieces of data can be alternatively stored in two memories.

Referring to FIG. 4, when the data of the ECC cluster that is equally divided by 4 and stored in the primary memory 102 as illustrated in FIG. 3 is read, when the secondary memory 106 includes first and second memories 401 and 402 (FIG. 4), each having a size of 62×304 bytes, the controller 103 stores the data of the region 301 of the primary memory 102 in the first memory 401 included in the secondary memory 106, stores the data of the region 302 of the primary memory 102 in the second memory 402 included in the secondary memory 106, stores the data of the region 303 of the primary memory 102 in the first memory 401 included in the secondary memory 106, and stores the data of the region 304 of the primary memory 102 in the second memory 402 included in the secondary memory 106. It is understood, however, that the controller 103 is not limited to storing the data of the primary memory 102 in this fashion, and may instead store the data in a different order in the first and second memories 401 and 402.

If data is completely stored in the first memory 401 included in the secondary memory 106, the recording processing unit 107 reads the data stored in the first memory 401 and records the read data onto the disc 101 by interleaving the read data. During this operation, data transmitted from the scrambler 105 or the controller 103 is stored in the second memory 402.

If the data stored in the first memory 401 is completely read, the recording processing unit 107 reads the data stored in the second memory 402 and records the read data onto the disc 101 by interleaving the read data. During this operation, data transmitted from the scrambler 105 or the controller 103 is stored in the first memory 401.

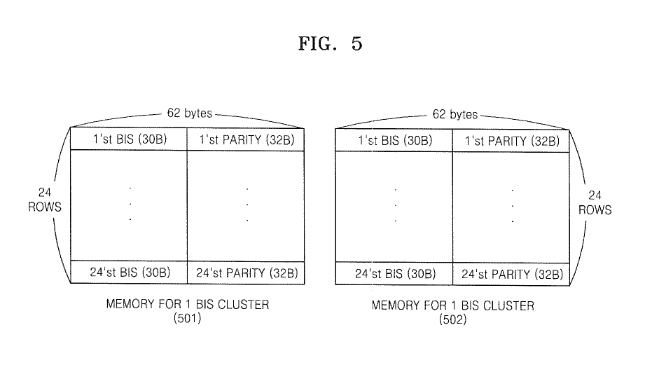

According to an aspect of the present invention, the secondary memory 106 is configured to further include two memories to store BIS clusters by using the two memories 401 and 402 illustrated in FIG. 4 to store LDC clusters. The two memories to store BIS clusters are the two memories 501 and 502 illustrated in FIG. 5, with each of the memories 501 and 502 corresponding to a BIS cluster, and are operated for two ECC clusters stored in the primary memory 102. That is, a BIS cluster included in one ECC cluster stored in the primary memory 102 can be stored in the memory 501, and another BIS cluster included in another ECC cluster stored in the primary memory 102 can be stored in the memory 502. It is understood that more than two memories may be used to store BIS clusters.

As described above, in order to store an ECC cluster stored in the primary memory 102 in the secondary memory 106, the controller 103 is configured to transmit data read from the primary memory 102 by determining which line of the lines L1, L2, and L3 (FIG. 3) the read data is transmitted through based on physical locations of the read data.

According to an aspect of the present invention, the secondary memory 106 is a Static Random Access Memory (SRAM). However, the secondary memory 106 is not limited to being an SRAM, and may instead be various other types of memories, such as, for example, a DRAM, an eDRAM, an SDRAM.

The recording processing unit 107 modulates the interleaved data and records the modulated data onto the disc 101. According to an aspect of the present invention, the data recorded onto the disc 101 has a pattern in which LDC clusters and BIS clusters are alternately arranged. However, the data is not limited to being recorded onto the disc 101 in this pattern, and may be recorded in other patterns instead.

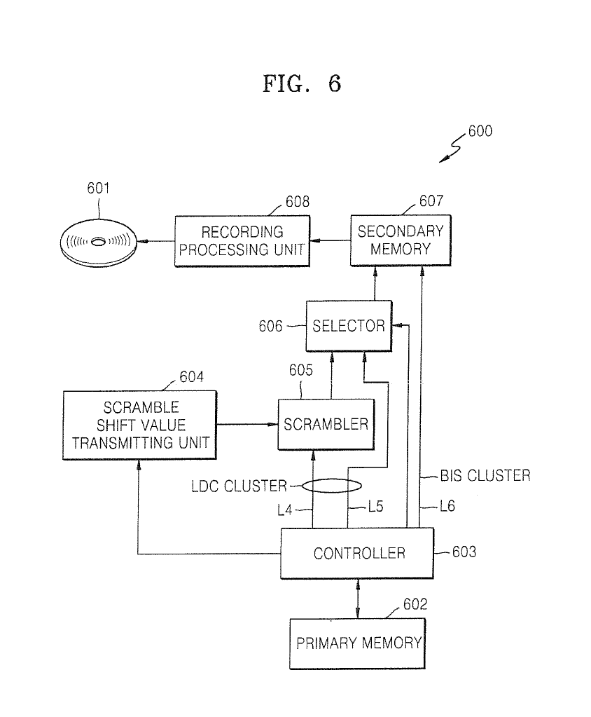

FIG. 6 is a block diagram of a high-speed recording apparatus 600 according to another embodiment of the present invention. Referring to FIG. 6, the high-speed recording apparatus 600 is used with a disc 601 and includes a primary memory 602, a controller 603, a scramble shift value transmitting unit 604, a scrambler 605, a selector 606, a secondary memory 607, and a recording processing unit 608.

The disc 601, the primary memory 602, the scramble shift value transmitting unit 604, the scrambler 605, the secondary memory 607, and the recording processing unit 608, which are illustrated in FIG. 6, operate and are configured similarly to the disc 101, the primary memory 102, the scramble shift value transmitting unit 104, the scrambler 105, the secondary memory 106, and the recording processing unit 107, respectively, which are illustrated in FIG. 1.

The controller 603 operates and is configured similarly to the controller 103 illustrated in FIG. 1, with the exception that, unlike the controller 103 illustrated in FIG. 1, the controller 603 transmits both data frames and LDC parities contained in an LDC cluster read from the primary memory 602 via a line L4 and a line L5. Thus, the scrambler 605 scrambles data contained in the LDC cluster.

The selector 606 selects one of the scrambled data input from the scrambler 605 and data input from the controller 603 and transmits the selected data to the secondary memory 607. The controller 603 controls the selection operation of the selector 606 based on physical locations of the data transmitted to the scrambler 605 and the selector 606.

That is, if data read from the primary memory 602 is data contained in a data frame of the LDC cluster, the controller 603 controls the selector 606 to select scrambled data input from the scrambler 605 and transmit the selected data to the secondary memory 607. On the other hand, if data read from the primary memory 602 is data contained in an LDC parity of the LDC cluster, the controller 603 controls the selector 606 to select data input via the line L5 and transmit the selected data to the secondary memory 607.

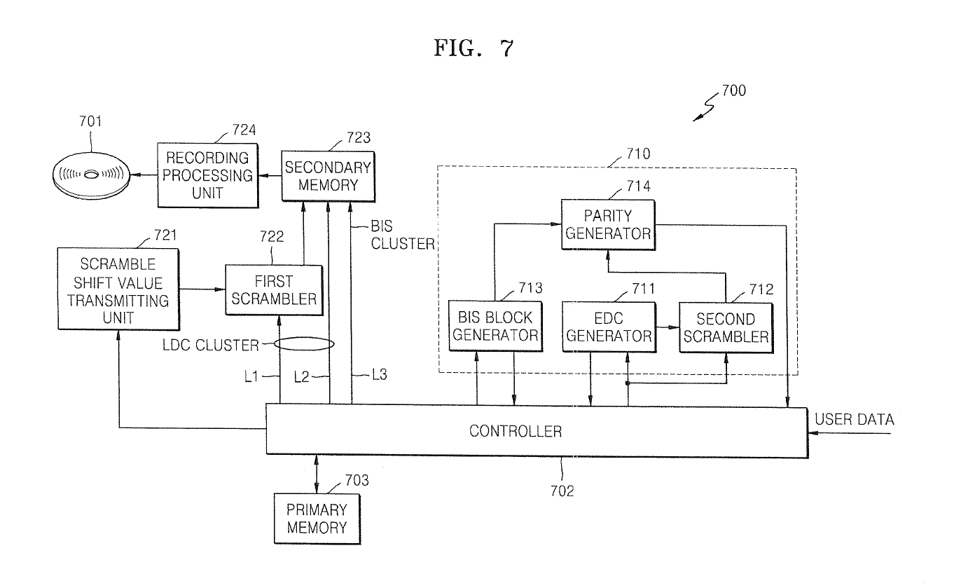

FIG. 7 is a block diagram of a high-speed recording apparatus 700 according to another embodiment of the present invention. Referring to FIG. 7, the high-speed recording apparatus 700 is used with yet another disc 701 and includes a controller 702, a primary memory 703, an ECC cluster generator 710, a scramble shift value transmitting unit 721, a first scrambler 722, a secondary memory 723, and a recording processing unit 724.

The disc 701, the primary memory 703, the scramble shift value transmitting unit 721, the scrambler 722, the secondary memory 723, and the recording processing unit 724, which are illustrated in FIG. 7, operate and are configured similarly to the disc 101, the primary memory 102, the scramble shift value transmitting unit 104, the scrambler 105, the secondary memory 106, and the recording processing unit 107, respectively, which are illustrated in FIG. 1.

When user data is transmitted from a host (not shown) on a frame-by-frame basis, the controller 702 stores user data contained in 32 data frames in a main data area (refer to FIG. 2) of the primary memory 703. According to an aspect of the present invention, the amount of transmitted user data is 32 frames×2048 bytes. The controller 702 reads main data (or user data) stored in the primary memory 703 and transmits the read data to the ECC cluster generator 710. It is understood that the amount of transmitted user data may be larger or smaller than 32 frames×2048 bytes.

The ECC cluster generator 710 generates data required to store an ECC cluster having the data structure illustrated in FIG. 2 in the primary memory 703. In order to perform this operation, the ECC cluster generator 710 includes an EDC generator 711, a second scrambler 712, a BIS block generator 713, and a parity generator 714. These components may be configured separately or be integrally combined.

If the user data read from the primary memory 703 is input, the EDC generator 711 generates a 4-byte EDC for each data frame. Thus, since an ECC cluster includes 32 data frames, the EDC generator 711 generates 32 4-byte EDCs for one ECC cluster. The EDC generator 711 generates each EDC using a generator polynomial G(X)=x³²+x³¹+x⁴+1. Each of the generated 4-byte EDCs are transmitted to the controller 702 and the second scrambler 712. It is understood that the EDC generator 711 may instead use other polynomials to achieve approximately the same EDCs for each data frame.

The controller 702 stores the transmitted EDCs in the primary memory 703 so that each EDC is stored immediately next to user data in each data frame. That is, the controller 702 stores the transmitted EDCs so that a 4-byte EDC is stored immediately next to user data of a data frame.

The second scrambler 712 scrambles the data of 32 frames×2052 bytes obtained by adding a 4-byte EDC for each data frame to the user data of 32 frames×2048 bytes transmitted by the controller 702. The second scrambler 712 scrambles the data of 32 frames×2052 bytes using an LFSR that operates based on PSNs transmitted by the controller 702. The scrambled data is transmitted to the parity generator 714. According to an aspect of the present invention, the scrambled data is defined as an LDC block of 304 rows×216 bytes (124 words). The controller 702 transmits the PSNs to the second scrambler 712 based on the user data transmitted from the host. It is understood that the scrambled data is not limited to being defined as an LDC block of 304 rows×216 bytes (124 words), and may instead be defined as a bigger or smaller LDC block.

When 16 Address Unit Numbers (AUNs) (16 addresses×9 bytes) and 32 pieces of User Control Data (UCD) (32 units×18 bytes) are transmitted from the controller 702, the BIS block generator 713 generates BIS blocks, each having 24 rows×30 bytes. The generated BIS blocks are transmitted to the controller 702 and the parity generator 714. The controller 702 receives the AUNs and the UCD from the host. When the controller 702 and the parity generator 714 receive the generated BIS blocks, the controller 702 stores two continuous BIS blocks in every other sector in the primary memory 703. Alternatively, the controller 702 may store the BIS blocks in other fashions, such as storing two continuous BIS blocks in every third sector in the primary memory 703.

When the scrambled data blocks are transmitted from the second scrambler 712, the parity generator 714 generates a 32-byte parity for each row. Thus, since one ECC cluster has 304 rows, the parity generator 714 generates 304 32-byte parities (32×304 bytes). The generated parities are LDC parities since the scrambled data blocks are data frames in an LDC cluster. The LDC parities are transmitted to the controller 702. Thus, the controller 702 stores 19 continuous 32-byte LDC parities in every other sector in the primary memory 703, as illustrated in FIG. 2. However, it is understood that the controller 702 is not limited to storing the LCD parities in every other sector in the primary memory 703, and may store the LDC parities in other fashions instead.

When the BIS blocks are transmitted from the BIS block generator 713, the parity generator 714 generates BIS parities. Since the BIS blocks correspond to 24 rows, the parity generator 714 generates 24 32-byte BIS parities (32×24 bytes). The BIS parities are transmitted to the controller 702. The controller 702 stores the BIS parities in the primary memory 703 so that two 32-byte BIS parities and two 30-byte BIS blocks are alternately arranged in every other sector, as illustrated in FIG. 2. Since 24 BIS blocks and 24 BIS parities are generated, the controller 702 stores the 24 BIS blocks and the 24 BIS parities in the primary memory 703 so that the 24 BIS blocks and the 24 BIS parities are stored up to the 24^{th} sector in one ECC cluster.

Accordingly, the ECC cluster having the data structure illustrated in FIG. 2 is stored in the primary memory 703. A process of transmitting the ECC cluster stored in the primary memory 703 to the secondary memory 723 is similar to the process of transmitting the ECC cluster stored in the primary memory 102 to the secondary memory 106 illustrated in FIG. 1 and described above.

The high-speed recording apparatuses 100, 600, and 700 illustrated in FIGS. 1, 6, and 7, respectively, may be included in optical disc drives which rotate the discs 101, 601, and 701, respectively to perform data recording. Additionally, the high-speed recording apparatuses 100, 600, and 700 may be components within recording and reproducing apparatuses which perform both data recording and data reproduction.

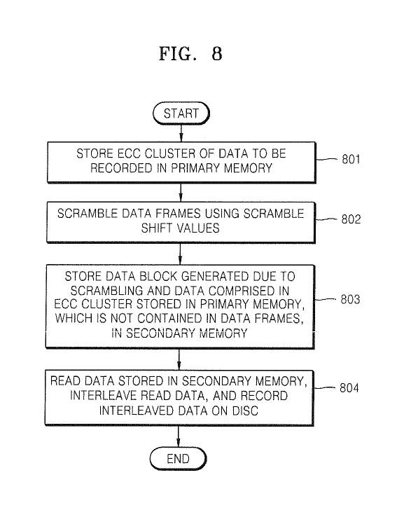

FIG. 8 is a flowchart of a high-speed recording method according to an embodiment of the present invention. The high-speed recording method illustrated in FIG. 8 will now be described with reference to the high-speed recording apparatus 700 illustrated in FIG. 7.

At least one ECC cluster of data that is to be recorded is stored in the primary memory 703 in operation 801. The data to be recorded includes user data transmitted from the host. When the disc 701 is a BD, the ECC cluster is generated based on the user data contained in the 32 data frames illustrated in FIG. 2 and stored in the primary memory 703.

The ECC cluster includes an LDC cluster and a BIS cluster of the data to be recorded, as illustrated in FIG. 2. The LDC cluster includes the data frames and LDC parities, and the BIS cluster includes BIS blocks and BIS parities. In the ECC cluster, data which is not contained in the data frames includes the LDC parities and the BIS cluster. The data frames include the user data and the EDCs that have not been scrambled.

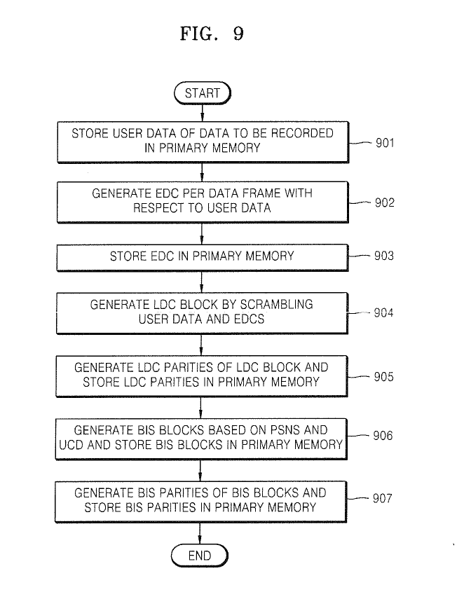

The process of storing the ECC cluster in the primary memory 703 will now be described with reference to FIG. 9. Referring to FIG. 9, the controller 702 stores the user data of the 32 data frames in the primary memory 703 in operation 901. The EDC generator 711 generates a 4-byte EDC for each data frame with respect to the user data read from the primary memory 703 in operation 902. Thus, 32×4-byte EDCs are generated. The controller 702 stores the 32×4-byte EDCs in the primary memory 703 in operation 903. More specifically, when the 32×4-byte EDCs are stored in the primary memory 703 in operation 903, the controller 702 assigns a 4-byte EDC to one data frame and stores the 4-byte EDC immediately next to corresponding user data of the data frame.

The second scrambler 712 generates an LDC block of the ECC cluster by scrambling the user data transmitted from the primary memory 703 and the generated EDCs in operation 904. The LDC block according to an aspect of the present invention has a size of 304 rows×216 bytes. However, it is understood that the LDC block may be bigger of smaller than 304 rows×216 bytes.

It operation 905, the parity generator 714 generates LDC parities of the LDC block and the controller 702 stores the generated LDC parities in the primary memory 703. In operation 906, the BIS block generator 713 generates BIS blocks based on PSNs and UCD transmitted from a host, and the controller 702 stores the generated BIS blocks in the primary memory 703.

When the parity generator 714 generates BIS parities of the BIS blocks, the controller 702 stores the generated BIS parities in the primary memory 703 in operation 907. According to an aspect of the present invention, the LDC parities, the BIS blocks, and the BIS parities are sequentially stored in the primary memory 703 as illustrated in FIG. 2. However, the LDC parities, the BIS blocks, and the BIS parities are not limited to being sequentially stored, and may instead be stored in a non-sequential order.

Referring back to FIG. 8, the data frames read from the primary memory 703 are scrambled in operation 802 using scramble shift values stored in advance. The scrambling is performed based on physical locations of the scramble shift values on the data frames and physical locations of data contained in the data frames. According to an aspect of the present invention, the scramble shift values are updated on an ECC cluster-by-ECC cluster basis. However, the scramble shift values are not limited to being updated on an ECC-cluster-by-ECC-cluster basis, and may instead be updated on another basis, such as, for example, by a fraction of an ECC cluster or by multiple ECC clusters. Data blocks generated by the scrambling, and data contained in the ECC cluster stored in the primary memory 703 which is not contained in the data frames, are read and stored in the secondary memory 723 in operation 803.

As described above, when the data frames and the data which is not contained in the data frames are read from the primary memory 703, the ECC cluster stored in the primary memory 703 is equally divided into N pieces of data in a perpendicular direction and read as illustrated in FIGS. 1 and 3. When the ECC cluster stored in the primary memory 703 is equally divided into N pieces of data in the perpendicular direction and read, the secondary memory 723 stores the N pieces of data by alternately using a plurality of memories having a size according to the N pieces of data (as illustrated in FIG. 4).

Finally, the data stored in the secondary memory 723 is interleaved and recorded onto the disc 701 in operation 804.

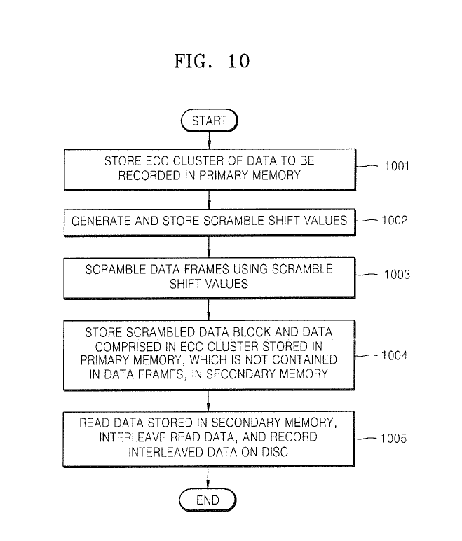

FIG. 10 is a flowchart of a high-speed recording method according to another embodiment of the present invention. FIG. 10 illustrates a process of generating and storing scramble shift values which is added to the high-speed recording method illustrated in FIG. 8. Thus, operation 1001 illustrated in FIG. 10 is similar to operation 801 illustrated in FIG. 8, and operations 1003, 1004, and 1005 illustrated in FIG. 10 are respectively similar to operations 802, 803, and 804 illustrated in FIG. 8.

In operation 1002 illustrated in FIG. 10, scramble shift value corresponding to each data frame is generated based on PSNs contained in BIS blocks and the generated scramble shift value is stored in the scramble shift value transmitting unit 104. The generation and storage of the scramble shift values in FIG. 10 is achieved in the same manner as described with reference to the scramble shift value transmitting unit 104 illustrated in FIG. 1.

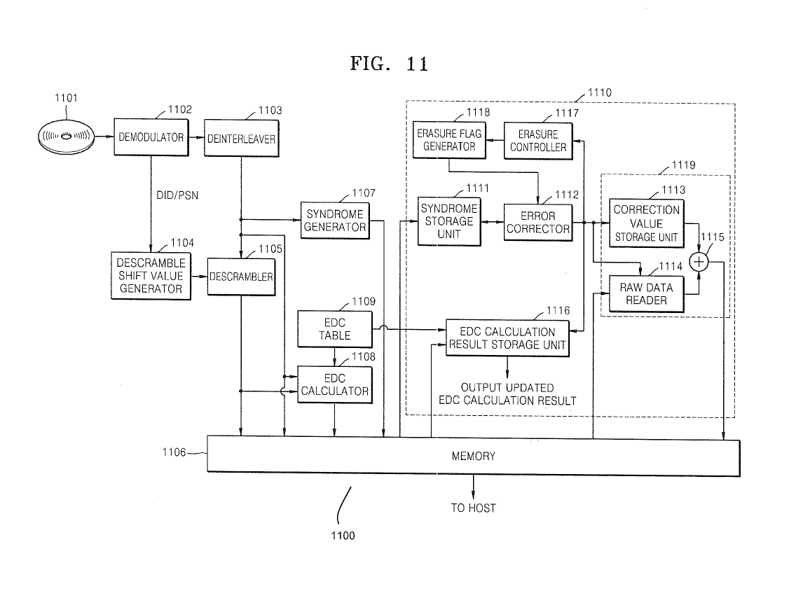

FIG. 11 is a block diagram of a high-speed reproducing apparatus 1100 according to an embodiment of the present invention. Referring to FIG. 11, the high-speed reproducing apparatus is used with a disc 1101 and includes a demodulator 1102, a deinterleaver 1103, a descramble shift value generator 1104, a descrambler 1105, a memory 1106, a syndrome generator 1107, an EDC calculator 1108, an EDC table 1109, and an error correction unit 1110.

The disc 1101 may be various types of optical discs, such as, for example, a DVD/HD-DVD type or a BD type. Furthermore, the disc 1101 may be a single-layer or multi-layer disc.

The demodulator 1102 demodulates data read from the disc 1101. The deinterleaver 1103 deinterleaves the data demodulated by the demodulator 1102. The deinterleaver 1103 includes a plurality of memories in order to reduce a memory size, and deinterleaves the demodulated data by alternately using memories within the plurality of memories.

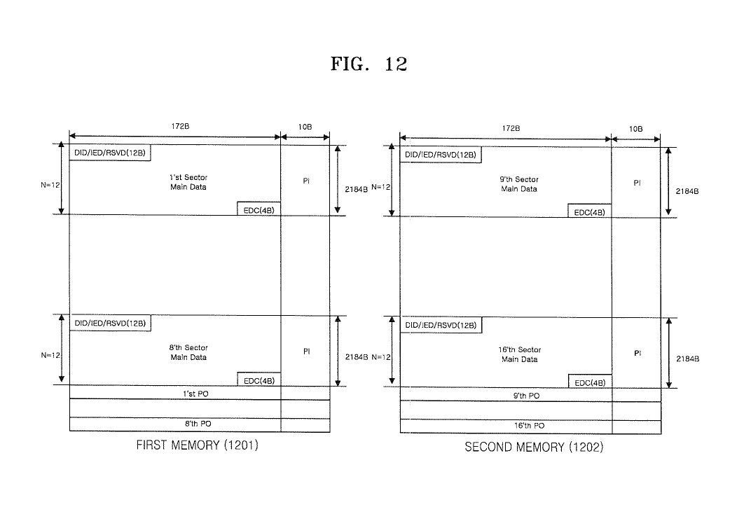

That is, when the disc 1101 is the DVD/HD-DVD type, the deinterleaver 1103 stores demodulated data of an 8-sector size ((91×26=2366 bytes)×8) in a first memory 1201 and demodulated data of a subsequent 8-sector size in a second memory 1202, as illustrated in FIG. 12, and simultaneously deinterleaves a Parity Output (PO) portion. When the disc 1101 is the BD type, the deinterleaver 1103 stores demodulated data of a 4-sector size ((152×31=4712 bytes)×4) in the first memory 1201 and demodulated data of a subsequent 4-sector size in the second memory 1202 and simultaneously performs the deinterleaving in a PI codeword direction. When the disc 1101 is the BD type, a memory structure used in the deinterleaving is similar to that of the first and the second memories 401 and 402 illustrated in FIG. 4.

When the disc 1101 is the DVD/HD-DVD type, the descramble shift value generator 1104 generates descramble shift values using Data Identification Data (DID) output from the demodulator 1102. When the disc 1101 is the BD type, the descramble shift value generator 1104 generates descramble shift values using PSNs output from the demodulator 1102. A method of generating descramble shift values is similar to the method of generating scramble shift values in data recording.

The descrambler 1105 descrambles data contained in a data block among the deinterleaved data output from the deinterleaver 1103 using the descramble shift value output from the descramble shift value generator 1104. The data block includes main data and EDCs, regardless of whether the disc 1101 is the DVD/HD-DVD type or the BD type. The data descrambled by the descrambler 1105 is stored in the memory 1106. Data that has not been descrambled (non-descrambled data) among the deinterleaved data output from the deinterleaver 1103 is stored in the memory 1106. The non-descrambled data of the deinterleaved data output from the deinterleaver 1103 includes all data excluding the main data and the EDCs. For example, when the disc 1101 is the DVD/HD-DVD type, PIs/POs are the non-descrambled data, and when the disc 1101 is the BD type, PIs are the non-descrambled data.

The syndrome generator 1107 generates syndromes using the deinterleaved data output from the deinterleaver 1103. That is, when the disc 1101 is the DVD/HD-DVD type, the syndrome generator 1107 generates PI/PO syndromes, and when the disc 1101 is the BD type, the syndrome generator 1107 generates PI syndromes for BIS/LDC. According to an aspect of the present invention, the syndromes are generated on a codeword-by-codeword basis, and the size of syndromes is the same as a parity size. If no error exists in a codeword unit, a corresponding syndrome is generated as 0, and if errors exist in a codeword unit, a corresponding syndrome is generated as a non-zero value. The syndrome generator 1107 stores the generated syndromes in the memory 1106. It is understood that the syndromes are not limited to being generated on a codeword-by-codeword basis in each aspect of the present invention, and may instead be generated on another basis, such as on a fraction of a codeword basis, a multiple codeword basis, or a combination thereof.

The EDC calculator 1108 calculates each EDC using the non-descrambled data of the deinterleaved data output from the deinterleaver 1103, the descrambled data output from the descrambler 1105, and the EDC table 1109. That is, when the disc 1101 is the DVD/HD-DVD type, since the data stored in the memories included in the deinterleaver 1103 has continuity, the EDC calculator 1108 calculates each EDC using the non-descrambled data of the deinterleaved data output from the deinterleaver 1103 and the descrambled data output from the descrambler 1105 without using the EDC table 1109. However, when the disc 1101 is the BD type, since the data stored in the memories included in the deinterleaver 1103 does not have continuity, the EDC calculator 1108 calculates each EDC using the descrambled data output from the descrambler 1105 and the EDC table 1109.

When the disc 1101 is the BD type, the EDC calculator 1108 reads a value stored in the EDC table 1109 using location values and uses the read value as an EDC calculation result value. The EDC table 1109 is generated by performing modular division using a generator polynomial G(x), such as, for example, G(X)=x³²+x³¹+x⁴+1.

The memory 1106 stores the descrambled data output from the descrambler 1105, the data that is not contained in the data block among the deinterleaved data output from the deinterleaver 1103, the syndromes generated by the syndrome generator 1107, and the EDC calculation result value output from the EDC calculator 1108.

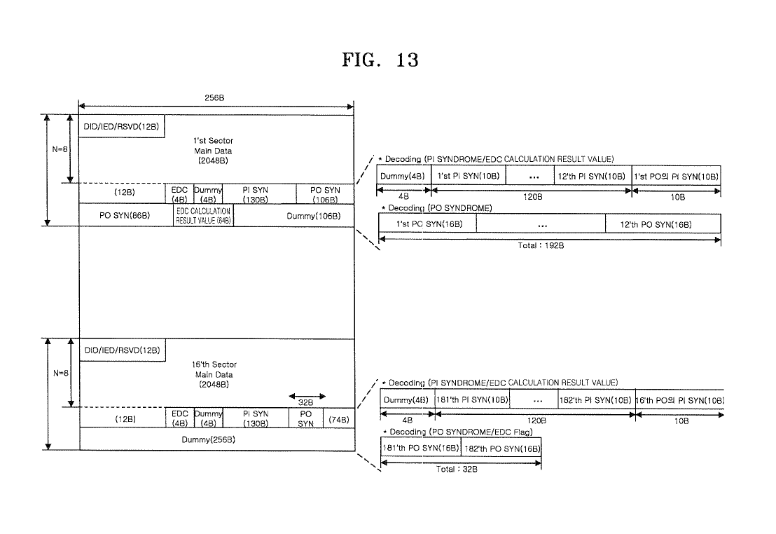

When the disc 1101 is the DVD/HD-DVD type, the memory 1106 stores the data in the memory map illustrated in FIG. 13. The data illustrated in FIG. 13 is defined as a single ECC cluster. In FIG. 13, PI SYNs and PO SYNs correspond to the syndromes.

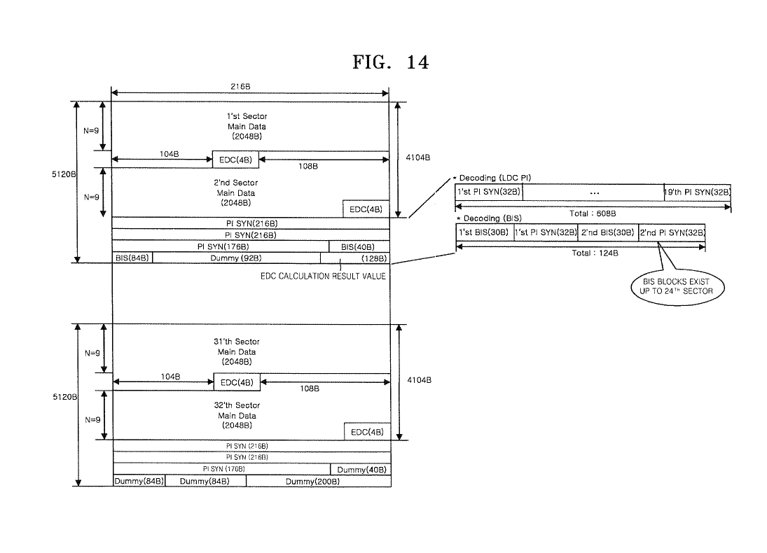

When the disc 1101 is the BD type, the memory 1106 stores the data in the memory map illustrated in FIG. 14. As with FIG. 13, the data illustrated in FIG. 14 is defined as a single ECC cluster. In FIG. 14, PI SYNs correspond to the syndromes.

The memory 1106 is implemented so that a controller (not shown) can perform functions similar to the controllers 103, 603, and 702 illustrated in FIGS. 1, 6, and 7, respectively, stores data output from other components in the memory map illustrated in FIG. 13 or 14, and/or reads data stored in the memory map illustrated in FIG. 13 or 14.

The error correction unit 1110 performs error correction of the data stored in the memory 1106 using the syndromes stored in the memory 1106. The data to be error-corrected includes the main data, the syndromes, and, in case the memory map illustrated in FIG. 13 or 14 is used, the EDC calculation result value. However, among the main data stored in the memory 1106, data in which an error has occurred is updated, but the syndromes and the EDC calculation result value are not updated.

In order to perform the above-described operation, the error correction unit 1110 includes a syndrome storage unit 1111, an error corrector 1112, a corrector 1119, an EDC calculation result storage unit 1116, an erasure controller 1117, and an erasure flag generator 1118.

The syndrome storage unit 1111 stores the syndromes read from the memory 1106. The error corrector 1112 performs the error correction using the syndromes stored in the syndrome storage unit 1111. For example, if a syndrome read from the memory 1106 is 0, this value indicates that no error exists in corresponding codewords, and therefore the error correction is unnecessary. Thus, the error corrector 1112 skips the error correction process. However, if the syndrome read from the memory 1106 is not 0, this value indicates that an error exists in corresponding codewords, and the error corrector 1112 obtains a location at which the error has occurred (hereinafter, an error location) and a value to be corrected (hereinafter, a correction value). Information indicating whether the error in the corresponding codewords is correctable is transmitted to the erasure controller 1117, the error location is transmitted to a raw data reader 1114 included in the corrector 1119, and the correction value is transmitted to a correction value storage unit 1113 included in the corrector 1119. The error correction result of the error corrector 1112 is transmitted to the EDC calculation result storage unit 1116.

The corrector 1119 corrects the data stored in the memory 1106 based on the error location and the correction value. The corrector 1119 reads raw data corresponding to each error location from the memory 1106 using the raw data reader 1114 based on the error location, performs an exclusive OR operation on a corresponding correction value stored in the correction value storage unit 1113 and the read raw data using a logic calculator 1115, and stores the result of the exclusive OR operation in a location of the memory 1106 corresponding to the error location. Thus, the corrector 1119 can be defined as an updating unit.

The EDC calculation result storage unit 1116 stores the EDC calculation result value read from the memory 1106 and updates the EDC calculation result value based on the error correction result of the error corrector 1112. When the error correction is performed by the error corrector 1112, the EDC calculation result value is updated to an error-corrected EDC calculation result. The syndrome storage unit 1111 also updates a syndrome of codewords in which an error has occurred among the syndromes read from the memory 1106 based on the error correction result of the error corrector 1112.

When information on whether each codeword is correctable is transmitted from the error corrector 1112, the erasure controller 1117 controls the erasure flag generator 1118 to generate an erasure flag in each non-corrected codeword based on the information on whether each codeword is correctable. Thus, the erasure flag generator 1118 generates one erasure flag per codeword. The erasure flag generator 1118 transmits the generated erasure flags to the error corrector 1112. Thus, the error corrector 1112 performs the erasure correction based on the erasure flags in an iterative correction process of one ECC cluster at a time. For example, if erasure flags are generated for codewords which cannot be corrected in PI correction, since error location information of the codewords for which erasure flags are generated is already known in PO correction, an error correction capability is increased. It is understood that the error corrector 1112 is not limited to performing the erasure correction based on the erasure flags in an iterative correction process of one ECC cluster at a time, and may instead perform erasure correction based on the erasure flags in a process which uses more or less than one ECC cluster at a time.

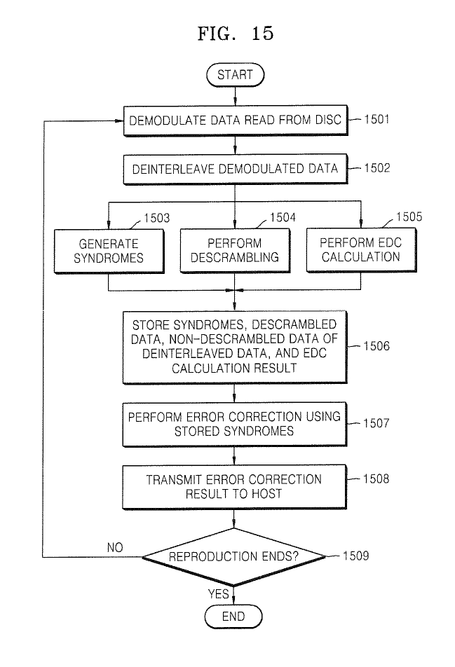

FIG. 15 is a flowchart of a high-speed reproducing method according to an embodiment of the present invention. The high-speed reproducing method illustrated in FIG. 15 will now be described with reference to the high-speed reproducing apparatus 1100 illustrated in FIG. 11.

Data read from the disc 1101 is demodulated in operation 1501. The demodulated data is deinterleaved in operation 1502. The deinterleaving is performed by alternately using a plurality of memories, as illustrated in FIG. 11.

A syndrome for each codeword is generated using the deinterleaved data in operation 1503. For example, each syndrome can be generated by dividing the deinterleaved data by the generator polynomial G(x), such as, for example, G(X)=x³²+x³¹+x⁴+1. If an error exists in the deinterleaved data, a syndrome polynomial which is one degree lower than the generator polynomial G(x) is generated as a syndrome. If no error exists in the deinterleaved data, the generated syndrome is 0. When the disc 1101 is the DVD/HD-DVD type, PI syndromes and PO syndromes are generated. When the disc 1101 is the BD type, PI syndromes are generated. In the case of a BD, the PI syndromes can be defined as PI syndromes for BIS and LDC. The size of the generated syndromes is the same as a parity size.

Data contained in a data block among the deinterleaved data is descrambled using descramble shift values in operation 1504. When the disc 1101 is the DVD/HD-DVD type, the descramble shift values are generated based on demodulated DID. When the disc 1101 is the BD type, descramble shift values are generated based on demodulated PSNs. That is, in the case of a BD, since the deinterleaved data is not continuous, the descrambling is performed by generating a descramble shift value of 2052 bytes in advance and reading a shift value corresponding to a data location. Thus, when the disc 1101 is the BD type, the descramble shift value may be stored in advance.

EDCs are calculated using data that has not been descrambled among the deinterleaved data, the descrambled data, and an EDC table stored in advance in operation 1505. When the disc 1101 is the DVD/HD-DVD type, since the deinterleaved and stored data is continuous data, the EDCs are calculated using the data that has not been descrambled among the deinterleaved data and the descrambled data. However, when the disc 1101 is the BD type, data is not stored in a unit of an ECC block in the deinterleaving, and the stored data has a discontinuous data pattern. Thus, a residual value according to each location must be calculated as a value corresponding to the EDC calculation. Thus, the EDC table 1109 is generated using a result of modular division based on using a generator polynomial G(x), such as, for example, G(X)=x³²+x³¹+x⁴+1, in every predetermined degree, and the EDC table 1109 and the descrambled data are used in the EDC calculation.

The generated syndromes, the descrambled data, the data that has not been descrambled among the deinterleaved data, and the EDC calculation result value are stored in the memory 1106 in operation 1506. Thus, when the disc 1101 is the DVD/HD-DVD type, at least one ECC cluster having the memory map illustrated in FIG. 13 is stored in the memory 1106. When the disc 1101 is the BD type, at least one ECC cluster having the memory map illustrated in FIG. 14 is stored in the memory 1106.

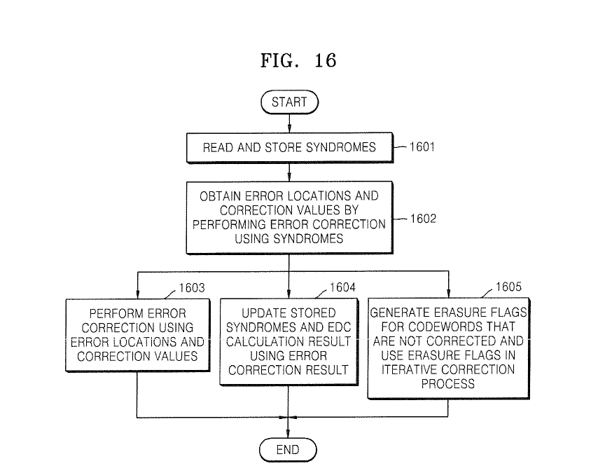

Data errors stored in the memory 1106 are corrected using the stored syndromes in operation 1507. An error correction range is similar to the error correction range described in relation to FIG. 11. The error correction is performed as illustrated in FIG. 16. FIG. 16 is a flowchart of an error correcting process using syndromes generated in the high-speed reproducing method illustrated in FIG. 15.

Referring to FIG. 16, the syndromes stored in the memory 1106 are read and stored, also known as re-stored, in operation 1601. In operation 1602, error locations and correction values are obtained by performing error correction using the error corrector 1112 to correct the errors of the stored syndromes stored in the syndrome storage unit 1111, as illustrated in FIG. 11.

The error correction is performed for the data stored in the memory 1106 based on the error locations and the correction values in operation 1603. The error correction technique may be, but is not necessarily, similar to the error correction technique performed by the corrector 1119 illustrated in FIG. 11. While performing the error correction, the syndromes and the EDC result value are updated based on the error correction result in operation 1604. Updating of the EDC result value is achieved by updating an EDC calculation result stored in the EDC calculation result storage unit 1116 illustrated in FIG. 11. The updated result may then be stored in the memory 1106. Alternatively, the updated result may be transmitted to a controller (not shown) without being stored in the memory 1106. The controller is a component used to control functions of an optical disc drive, such as controlling the function of the high-speed reproducing method according to an embodiment of the present invention.

In addition, erasure flags of codewords that have not been corrected in the error correction are generated in operation 1603, and erasure correction based on the erasure flags is performed in an iterative correction process in operation 1605. The use of the erasure flags in the iterative correction process may be, but is not necessarily, similar to the use of the erasure flags described above with reference to the erasure flag generator 1118 illustrated in FIG. 11.

Aspects of the present invention can also be embodied as computer readable codes on a computer readable recording medium. The computer readable recording medium is any data storage device that can store data which can be thereafter read by a computer system. Examples of the computer readable recording medium include read-only memory (ROM), random-access memory (RAM), CD-ROMs, magnetic tapes, floppy discs, optical data storage devices, and carrier waves (such as data transmission through the Internet). The computer readable recording medium can also be distributed over network coupled computer systems so that the computer readable code is stored and executed in a distributed fashion. For example, the generator polynomial G(X)=x³²+x³¹+x⁴+1, which is used by the EDC generator 711 (FIG. 7) to generate each 32 4-byte EDCs for one ECC cluster, may be embodied in a computer readable program on a hard disk of a computer.

As described above, according to aspects of the present invention, since scrambled main data is not written in a primary memory which stores an ECC cluster when data is recorded on a disc, such as the disc 101, at high speed, the number of read and write operations from and to the primary memory is reduced, resulting in a decrease in the operational frequency of an optical disc drive. Accordingly, power consumption of the optical disc drive is reduced, and the process of designing a chip to satisfy an operational frequency (or operation timing) of the optical disc drive is simplified.

In addition, by minimizing the size of a secondary memory to store data for interleaving, the size of chips included in optical disc drives is reduced. In data reproduction, by minimizing the size of a memory used to deinterleave data, the area of chips is reduced. Accordingly, aspects of the present invention increase price competitiveness of optical disc drives.

When data is reproduced at high speed, by independently performing a syndrome generation process, an EDC calculation process, and an error correction process using syndromes, even if the error correction is performed by exceeding a 1-ECC block decoding time, the exceeded 1-ECC block decoding time is not processed as an error correction failure, and thus an error correction load according to high-speed reproduction is reduced.

In addition, when error correction is performed to reproduce data using the apparatuses and methods according to aspects of the present invention, by reducing the number of read and write operations from and to a memory in which an ECC cluster is stored to decrease an operational frequency of an optical disc drive, power consumption is reduced, and is the process of designing a chip to satisfy the operational frequency of the optical disc drive is easier.

Although a few embodiments of the present invention have been shown and described, it would be appreciated by those skilled in the art that changes may be made in this embodiment without departing from the principles and spirit of the invention, the scope of which is defined in the claims and their equivalents.

What is claimed is:

1. A recording method comprising:
storing at least one Error Correction Code (ECC) data cluster in a primary memory;
scrambling data frames contained in the stored ECC data cluster using scramble shift values;
storing data in a secondary memory, the data comprising data which is not contained in the data frames and is contained in the ECC data cluster, and a data block generated by the scrambling of the data frames;
interleaving the data stored in the secondary memory; and
recording the interleaved data on a disc.

2. The recording method of claim 1, wherein the ECC data cluster comprises a Long Distance Code (LDC) cluster and a Burst Indicating Sub-code (BIS) cluster, and
the LDC cluster comprises the data frames.

3. The recording method of claim 2, wherein the data that is not contained in the data frames comprises LDC parities comprised in the LDC cluster and the BIS cluster, and
the BIS cluster comprises BIS blocks and BIS parities.

4. The recording method of claim 3, further comprising generating and storing the scramble shift values corresponding to the data frames based on Physical Sector Numbers (PSNs) comprised in the BIS blocks.

5. The recording method of claim 1, wherein the scrambling of the data frames comprises performing the scrambling based on physical locations of the scramble shift values corresponding to the data frames and physical locations of data comprised in the data frames.

6. The recording method of claim 1, wherein the scramble shift values are updated on an ECC-cluster-by-ECC-cluster basis.

7. The recording method of claim 1, wherein the data frames comprise user data and Error Detection Codes (EDCs) which have not been scrambled.

8. The recording method of claim 7, wherein the storing of the ECC cluster in the primary memory comprises:
storing the user data of a plurality of the data frames in the primary memory;
generating the EDCs of each of the data frames for the user data read from the primary memory;
storing the generated EDCs in the primary memory;
generating an LDC block of the ECC cluster by scrambling the user data read from the primary memory and the generated EDCs;
generating LDC parities of the generated LDC block and storing the generated LDC parities in the primary memory;
generating BIS blocks based on PSNs and User Control Data (UCD) and storing the generated BIS blocks in the primary memory; and
generating BIS parities of the BIS blocks and storing the generated BIS parities in the primary memory,
wherein the EDCs are stored in the primary memory so that each EDC is located immediately next to the user data of each of the data frames, and
the LDC parities, the BIS blocks, and the BIS parities are sequentially stored in the primary memory.

9. The recording method of claim 8, further comprising:
equally dividing the ECC data cluster stored in the primary memory into N pieces of data in perpendicular directions to each other; and
reading the N pieces of data,
wherein the storing of the data in the secondary memory comprises storing the data by alternately using a plurality of memories which has a size according to the N pieces of data.

10. The recording method of claim 8, wherein the generating of the EDCs comprises using a using a generator polynomial.

11. A recording apparatus comprising:
a primary memory to store at least one Error Correction Code (ECC) data cluster;
a scramble shift value transmitting unit to transmit scramble shift values based on physical sector numbers (PSNs);
a first scrambler to scramble data frames of the ECC data cluster read from the primary memory using the scramble shift values;
a secondary memory to store data, the data comprising data which is not contained in the data frames and is contained in the ECC data cluster read from the primary memory and a data block output from the first scrambler;
a recording processing unit to interleave the data read from the secondary memory and to record the interleaved data on a high-density disc; and
a controller to control read and/or write operations of the primary memory and the secondary memory, to control transmission of the ECC data cluster read from the primary memory, and to transmit the PSNs to the scramble shift value transmitting unit.

12. The recording apparatus of claim 11, wherein the ECC data cluster comprises a Long Distance Code (LDC) cluster and a Burst Indicating Sub-code (BIS) cluster,
the LDC cluster comprises the data frames, and
the BIS cluster comprises the PSNs.

13. The recording apparatus of claim 12, wherein the data that is not contained in the data frames comprises LDC parities contained in the LDC cluster and the BIS cluster,
the BIS cluster comprises BIS blocks and BIS parities, and
the BIS blocks comprise the PSNs.

14. The recording apparatus of claim 13, wherein the scramble shift value transmitting unit generates and stores a scramble shift value corresponding to a data frame based on the PSNs transmitted by the controller.

15. The recording apparatus of claim 14, wherein the first scrambler performs the scrambling based on physical locations of the scramble shift values on the data frames and physical locations of data comprised in the data block.

16. The recording apparatus of claim 11, wherein the scramble shift values are updated on an ECC-cluster-by-ECC-cluster basis.

17. The recording apparatus of claim 11, wherein the data frames comprise user data and Error Detection Codes (EDCs) which have not been scrambled.

18. The recording apparatus of claim 11, further comprising an ECC cluster generator to generate the ECC data cluster stored in the primary memory,
wherein the ECC cluster generator comprises:
an EDC generator to generate an EDC of each of the data frames for user data read from the primary memory by the controller;
a second scrambler to generate an LDC block of the ECC data cluster by scrambling the user data and the EDCs read from the primary memory;
a BIS block generator to generate BIS blocks based on the PSNs and User Control Data (UCD); and
a parity generator to generate LDC parities of the LDC block transmitted from the second scrambler and to generate BIS parities of the BIS blocks transmitted from the BIS block generator,
wherein the controller sequentially stores the user data corresponding to pluralities of the data frames, the EDCs, the LDC parities, the BIS blocks, and the BIS parities in the primary memory.

19. The recording apparatus of claim 11, wherein the controller equally divides the ECC cluster stored in the primary memory into N pieces of data in perpendicular directions to each other and reads the N pieces of data.

20. The recording apparatus of claim 19, wherein the secondary memory comprises a plurality of memories having a size according to the N pieces of data, and
the controller controls read and/or write operations of the plurality of memories so that the data read from the primary memory is alternately stored in the plurality of memories.

21. The recording apparatus of claim 18, wherein the EDC generator generates the EDCs of each of the data frames using a generator polynomial.

22. A reproducing method comprising:
demodulating data read from a disc;
deinterleaving the demodulated data;
generating syndromes using the deinterleaved data;
descrambling data contained in a data block among the deinterleaved data using descramble shift values;
calculating error detection codes (EDCs) using non-descrambled data among the deinterleaved data, the descrambled data, and an EDC table;
storing the descrambled data, the non-descrambled data, and the syndromes; and
correcting errors of the stored descrambled data and the stored non-descrambled data using the stored syndromes.

23. A reproducing apparatus comprising:
a demodulator to demodulate data read from a disc;
a deinterleaver to deinterleave the data demodulated by the demodulator;
a syndrome generator to generate syndromes using the data output from the deinterleaver;
a descrambler to descramble data contained in a data block among the deinterleaved data using descramble shift values;
an error detection code (EDC) calculator to calculate EDCs using non-descrambled data among the deinterleaved data, the data descrambled by the descrambler, and an EDC table;
a memory to store the descrambled data, the non-descrambled data, and the syndromes; and
an error correction unit to correct errors of the descrambled data and the non-descrambled data stored in the memory by reading the syndromes from the memory.

24. A recording method comprising:
storing an Error Correction Code (ECC) data cluster in a primary memory;
scrambling data frames contained in the stored ECC data cluster;
storing remaining data in a secondary memory, the remaining data comprising data in the ECC data cluster which is not contained in the data frames; and
recording the remaining data.

25. The recording method of claim 24, further comprising:
interleaving the remaining data stored in the secondary memory before the recording of the remaining data.

26. The recording method of claim 24, wherein the scrambling of the data frames comprises scrambling the data frames using scramble shift values.

27. The recording method of claim 26, wherein the ECC data cluster comprises a Long Distance Code (LDC) cluster and a Burst Indicating Sub-code (BIS) cluster, the LDC cluster comprises the data frames, the data that is not contained in the data frames comprises LDC parities comprised in the LDC cluster and the BIS cluster, and the BIS cluster comprises BIS blocks and BIS parities.

28. The recording method of claim 27, further comprising generating and storing the scramble shift values corresponding to the data frames based on Physical Sector Numbers (PSNs) comprised in the BIS blocks.

29. The recording method of claim 28, wherein the scramble shift values are updated on an ECC-cluster-by-ECC-cluster basis.

30. A reproducing method comprising:
reading data from a disc;
generating syndromes based on the read data;
descrambling data contained in a data block among the data;
calculating error detection codes (EDCs) using non-descrambled data among the read data and the descrambled data; and
correcting errors of the descrambled data and the non-descrambled data using the syndromes, wherein the generating of the syndromes, the calculating of the EDCs, and the correcting of the errors are performed independently of each other.

31. The reproducing method of claim 30, further comprising:
demodulating the read data; and
deinterleaving the demodulated data, wherein the demodulating and the deinterleaving are performed before the generating of the syndromes.

32. The reproducing method of claim 31, wherein the calculating of the EDCs further comprises using an EDC table, wherein the EDC table is generated by performing modular division using a generator polynomial.

33. The reproducing method of claim 31, wherein the deinterleaving is performed by alternately using a plurality of memories.

34. The reproducing method of claim 31, further comprising storing the descrambled data, the non-descrambled data and the syndromes after the calculating of the EDCs and before the correcting of the errors.

35. The reproducing method of claim 34, wherein the correcting of the errors comprises:
reading the stored syndromes and re-storing the syndromes;
obtaining error locations and correction values by performing the error correction using the syndromes which are re-stored; and
correcting the stored descrambled data and the stored non-descrambled data based on the error locations and correction values.
